(19) United States
(12) Patent Application Publication
(10) Pub. No.: US 2009/0090973 A1
(43) Pub. Date: Apr. 9, 2009

(54) SEMICONDUCTOR DEVICE AND METHOD OF MANUFACTURING THE SAME

(76) Inventors: Akihito TOHATA, Yokohama-shi (JP); Osamu HIRABAYASHI, Tokyo (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/244,097

(22) Filed: Oct. 2, 2008

(30) Foreign Application Priority Data
Oct. 3, 2007 (JP) 2007-260239

(51) Int. Cl. H01L 29/78; H01L 21/8234

(52) U.S. Cl. 257/368; 438/296; 257/E29.255; 257/E21.628

(57) ABSTRACT

A semiconductor device includes a device isolation insulating film which is provided in a semiconductor substrate, and an insulated-gate field-effect transistor which is disposed adjacent to the device isolation insulating film in a gate length direction, the insulated-gate field-effect transistor including a gate insulation film which is provided on the semiconductor substrate, a gate electrode which is provided on the gate insulation film, a pair of impurity diffusion layers which are provided spaced apart in the semiconductor substrate in a manner to sandwich the gate electrode, and a redundant impurity diffusion layer which is provided between the device isolation insulating film and one of the pair of impurity diffusion layers.

### CROSS-REFERENCE TO RELATED APPLICATIONS

This application is based upon and claims the benefit of priority from prior Japanese Patent Application No. 2007-260239, filed Oct. 3, 2007, the entire contents of which are incorporated herein by reference.

### BACKGROUND OF THE INVENTION

1. Field of the Invention

The present invention relates to a semiconductor device and a method of manufacturing the semiconductor device, and is applied, for example, to a transistor which is disposed adjacent to an STI (Shallow Trench Isolation).

2. Description of the Related Art

It is known that degradation occurs in a driving current of a transistor due to a stress (hereinafter referred to as “STI stress”) occurring from, e.g. an STI which is used as a device isolation insulating film (see, e.g. Jpn. Pat. Appln. KOKAI Publication No. 2005-064056). Thus, the driving current of the transistor varies depending on the distance from the gate of the transistor to the STI. In particular, the STI stress has become a serious problem with the progress of scaling of LSIs in recent years. Hence, there occurs a need to consider the STI stress, and the driving current of the transistor greatly varies depending on layouts.

For example, consideration is given to a case of a word line driver of an SRAM. Since the word line driver drives word lines of a memory cell array, it is necessary to dispose the word line driver within the row pitch of memory cells.

Transfer transistors, which are disposed in the word line driver, are arranged in such a layout that impurity diffusion layers, which are sources/drains, are shared by neighboring transistor transistors. If attention is paid to a transfer transistor which is positioned at a central part, the distance between the STI and the impurity diffusion layer of this transfer transistor is sufficiently long, and the distance from the STI is also sufficiently long. Thus, the influence of the STI stress on the transfer transistor at the central part is small.

On the other hand, a transfer transistor, which is positioned at a terminal end of the word line driver neighboring the STI, is disposed in such a layout that there is no transfer transistor which shares the impurity diffusion layer on the opposite side. Thus, the distance from the STI is a minimum distance that is determined by design rules. Hence, the transfer transistor, which is positioned at the terminal end of the word line driver, has a least distance from the STI. As a result, the driving current of the transfer transistor, which is positioned at the terminal end, tends to be much lower than the driving current of a transfer transistor which is positioned at the central part.

As described above, since the driving current of the transistor varies depending on the distance between the gate of the transistor and the STI, the driving current of the above-described transfer transistor, which is positioned at the terminal end, lowers and differs from the driving current of other transfer transistors. Consequently, an influence tends to occur in the timing of activating/de-activating the word lines.

The same tendency occurs in word line driving circuits of other memories, e.g. NAND flash memories, as well as SRAMs. The NAND flash memory is one of storage devices, whose scaling has been most developed in recent years. Thus, in the NAND flash memory, a greater influence tends to occur due to the decrease in driving current of the transistor, which is caused by the STI stress.

### BRIEF SUMMARY OF THE INVENTION

According to an aspect of the present invention, there is provided a semiconductor device comprising: a device isolation insulating film which is provided in a semiconductor substrate; and an insulated-gate field-effect transistor which is disposed adjacent to the device isolation insulating film in a gate length direction, the insulated-gate field-effect transistor including a gate insulation film which is provided on the semiconductor substrate, a gate electrode which is provided on the gate insulation film, a pair of impurity diffusion layers which are provided spaced apart in the semiconductor substrate in a manner to sandwich the gate electrode, and a redundant impurity diffusion layer which is provided between the device isolation insulating film and one of the pair of impurity diffusion layers.

According to another aspect of the present invention, there is provided a semiconductor device comprising: a first insulated-gate field-effect transistor including a gate insulation film which is provided on a semiconductor substrate, a gate electrode which is provided on the gate insulation film, a pair of impurity diffusion layers which are provided spaced apart in the semiconductor substrate in a manner to sandwich the gate electrode, and a redundant impurity diffusion layer which is provided in contact with one of the pair of impurity diffusion layers; and a second insulated-gate field-effect transistor which is disposed on the semiconductor substrate, adjacent to the first insulated-gate field-effect transistor in a gate length direction, the second insulated-gate field-effect transistor sharing the redundant impurity diffusion layer in contact with one of a pair of impurity diffusion layers thereof.

According to still another aspect of the present invention, there is provided a method of manufacturing a semiconductor device, comprising: forming a trench in a semiconductor substrate in a device isolation region, and burying an insulation film in the trench, thereby forming a device isolation insulating film; forming a line & space pattern of a multi-layer, which comprises a gate insulation film and a gate electrode, in a gate width direction on the semiconductor substrate in the device isolation region; doping impurities in the semiconductor substrate by using the pattern as a mask, and simultaneously forming an impurity diffusion layer which functions as a source/drain, and a redundant impurity diffusion layer which is interposed between the device isolation insulating film and the impurity diffusion layer in a gate length direction; and forming a contact wiring on the impurity diffusion layer.

### BRIEF DESCRIPTION OF THE SEVERAL VIEWS OF THE DRAWING

FIG. 1 is a perspective view showing a semiconductor device according to the outline of the present invention;

FIG. 2 is a block diagram for describing an example of the entire structure of a semiconductor device (SRAM) according to a first embodiment of the invention;

FIG. 3 is a circuit diagram showing an SRAM cell according to the first embodiment;

FIG. 4 is a plan view showing a word line driver of the semiconductor device according to the first embodiment;

FIG. 5 is a perspective view showing a structure in the first embodiment, which is indicated by a broken-line box in FIG. 4;

FIG. 6 is a graph showing the STI stress dependency of the semiconductor device according to the first embodiment;

FIG. 7 is a perspective view illustrating a fabrication step of the semiconductor device according to the first embodiment;

FIG. 8 is a perspective view illustrating a fabrication step of the semiconductor device according to the first embodiment;

FIG. 9 is a perspective view illustrating a fabrication step of the semiconductor device according to the first embodiment;

FIG. 10 is a plan view showing a word line driver of a semiconductor device according to a modification;

FIG. 11 is a plan view showing a semiconductor device according to a second embodiment of the invention;

FIG. 12 is a perspective view showing a structure in the second embodiment, which is indicated by a broken-line box in FIG. 11;

FIG. 13 is a plan view showing a semiconductor device according to a third embodiment of the invention;

FIG. 14 is a perspective view showing a structure in the third embodiment, which is indicated by a broken-line box in FIG. 13;

FIG. 15 is a block diagram for describing an example of the entire structure of a semiconductor device (NAND flash memory) according to a fourth embodiment of the invention;

FIG. 16 is a circuit diagram showing a block relating to the fourth embodiment;

FIG. 17 is a cross-sectional view showing a memory cell string according to the fourth embodiment; and

FIG. 18 is a circuit diagram showing a word line control circuit of the semiconductor device according to the fourth embodiment.

### DETAILED DESCRIPTION OF THE INVENTION

### Outline

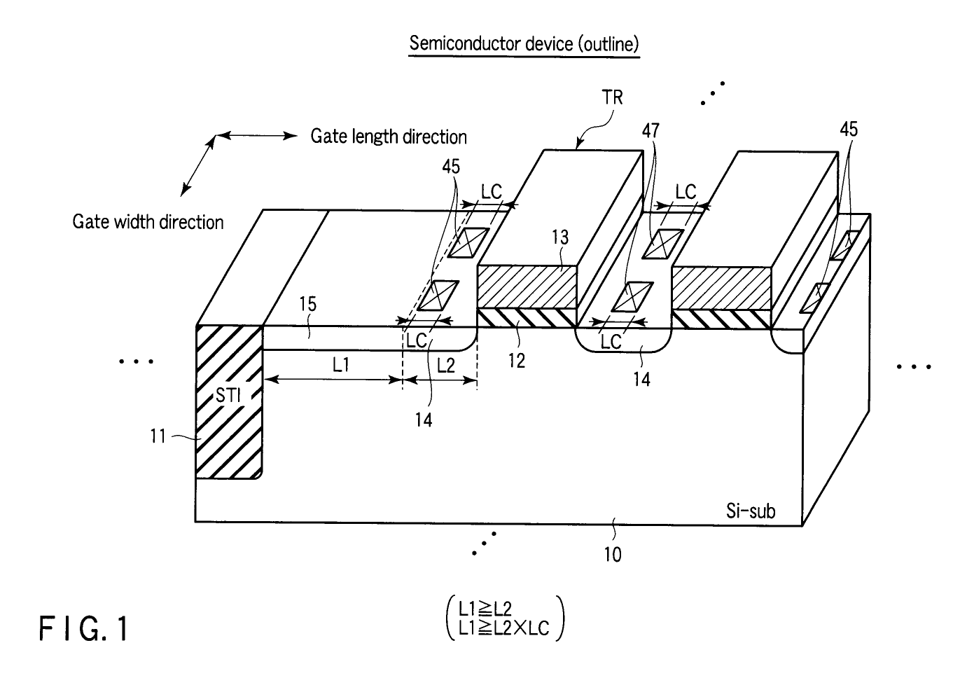

To begin with, referring to FIG. 1, the outline of the present invention is described.

An example of the invention proposes a semiconductor device which can relax a stress due to a device isolation insulating film, and can prevent a decrease in driving current.

The structure of the semiconductor device, as shown in FIG. 1, for example, comprises a device isolation insulating film 11 (STI: Shallow Trench Isolation, in this example) which is provided in a semiconductor substrate 10, and an insulated-gate field-effect transistor TR which is disposed adjacent to the device isolation insulating film 11 in a gate length direction. The insulated-gate field-effect transistor TR includes a gate insulation film 12 which is provided on the semiconductor substrate; a gate electrode 13 which is provided on the gate insulation film; a pair of impurity diffusion layers 14 which are provided spaced apart in the semiconductor substrate in a manner to sandwich the gate electrode; and a redundant impurity diffusion layer 15 which is provided between the device isolation insulating film and one of the pair of impurity diffusion layers.

The above-described structure includes the redundant impurity diffusion layer 15 which is provided between the device isolation insulating film 11 and one of the pair of impurity diffusion layers 14. Thus, such a layout structure can be realized that one of the impurity diffusion layers 14 is extended to such a distance as to be free from the influence of the stress due to the device isolation insulating film 11, and the stress (STI stress) due to the device isolation insulating film 11 can be relaxed. Therefore, a decrease in driving current of the transistor TR can be prevented.

The impurity diffusion layer 14 is defined as a diffusion layer which functions as a current path of the transistor TR and on a surface of which a contact wiring 45, 47 is provided. The redundant impurity diffusion layer 15 is defined as a diffusion layer, on a surface of which the contact wiring 45, 47 is not provided, and which has a length L1 in the gate length direction that is about double or more the length LC of the contact wiring 45, 47 in the gate length direction (L1≧2×LC).

The distance, at which the impurity diffusion layer 14 is free from the influence of the stress due to the device isolation insulating film 11, is, for example, about a length L1 in the gate length direction of the redundant impurity diffusion layer 15. Preferably, the length L1 should be the length L2 or more in the gate length direction of the impurity diffusion layer 14 (L1≧L2). To be more specific, as will be described later, the length L1 is about 1 μm or more (L1≧1 μm).

As has been described above, according to the above-described structure, the stress due to the device isolation insulating film (the STI in this example) 11 can be relaxed, and a decrease in driving current of the insulated-gate field-effect transistor TR can be prevented.

Next, some embodiments and a modification, which are considered the best modes of the invention, will now be described. In the description below, common parts are denoted by like reference numerals throughout the drawings.

### FIRST EMBODIMENT

### An Example in which the Invention is Applied to an SRAM

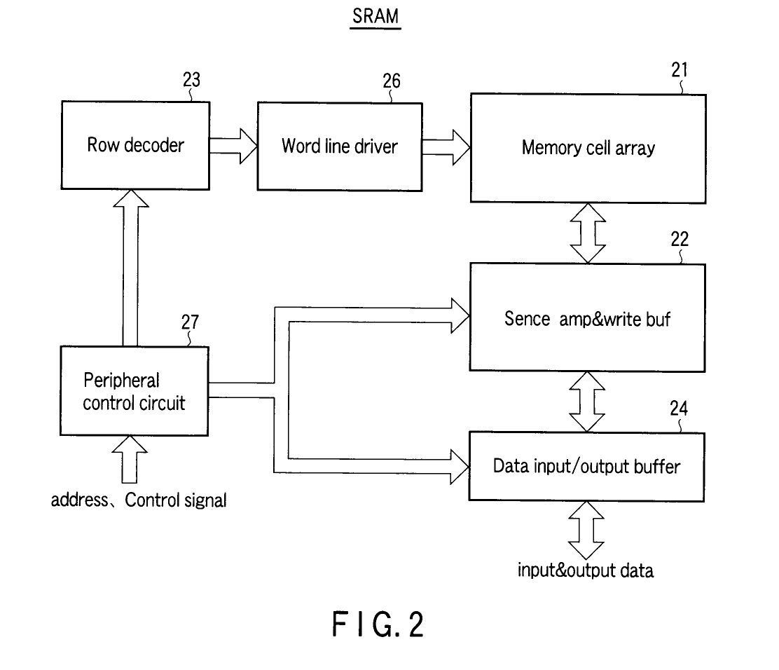

Referring to FIG. 2 to FIG. 6, a semiconductor device according to a first embodiment of the invention is described. In this embodiment, the invention is applied to a word line driver of an SRAM.

### 1. Example of Entire Structure

To begin with, an example of the entire structure of the SRAM is described with reference to FIG. 2. FIG. 2 is a block diagram showing the example of the entire structure of the SRAM according to the first embodiment of the invention.

As shown in FIG. 2, the SRAM comprises a memory cell array 21, a bit line load & column decoder circuit 22, a row decoder 23, a data input/output buffer 24, a word line driver 26 and a peripheral control circuit The memory cell array 21 is composed of a plurality of SRAM cells (memory cells) which are arranged in a matrix at intersections between word lines and bit lines. The word line driver 26, which controls the word lines, and the bit line load & column decoder circuit 22, which controls the bit lines, are connected to the memory cell array 21.

The bit line load & column decoder circuit 22 reads out data of the SRAM cells in the memory cell array 21 via the bit lines. In addition, the bit line load & column decoder circuit 22 includes a sense amplifier & write buffer. The data input/output buffer 24 and peripheral control circuit 27 are connected to the bit line load & column decoder circuit 22.

The data of the memory cells, which is read out by the bit line load & column decoder circuit 22, is output to an external host device via the data input/output buffer 24.

The host device is, for instance, a microcomputer, and receives the data that is output from the data input/output buffer. Further, the host device outputs various commands, addresses and control signals for controlling the operation of the SRAM. Input & output data, which is input/output to/from the data input/output buffer 24 from/to the host device, is supplied to the bit line load & column decoder circuit 22 via the data input/output buffer 24. On the other hand, the commands, addresses and control signals are supplied to the peripheral control circuit 27.

The word line driver 26 selects a word line in the memory cell array 21, and applies a voltage, which is necessary for read, write, to the selected word line.

The peripheral control circuit 27 is connected to the bit line load & column decoder circuit 22, row decoder 23 and data input/output buffer 24. The connected structural circuits are controlled by the peripheral control circuit 27. The peripheral control circuit 27 is connected to a control signal input terminal (not shown), and is controlled by the addresses and control signals which are input from the host device via the control signal input terminal.

The word line driver 26, bit line load & column decoder circuit 22 and peripheral control circuit 27 constitute a write circuit and a read circuit.

### 2. Structure Example of SRAM Cell

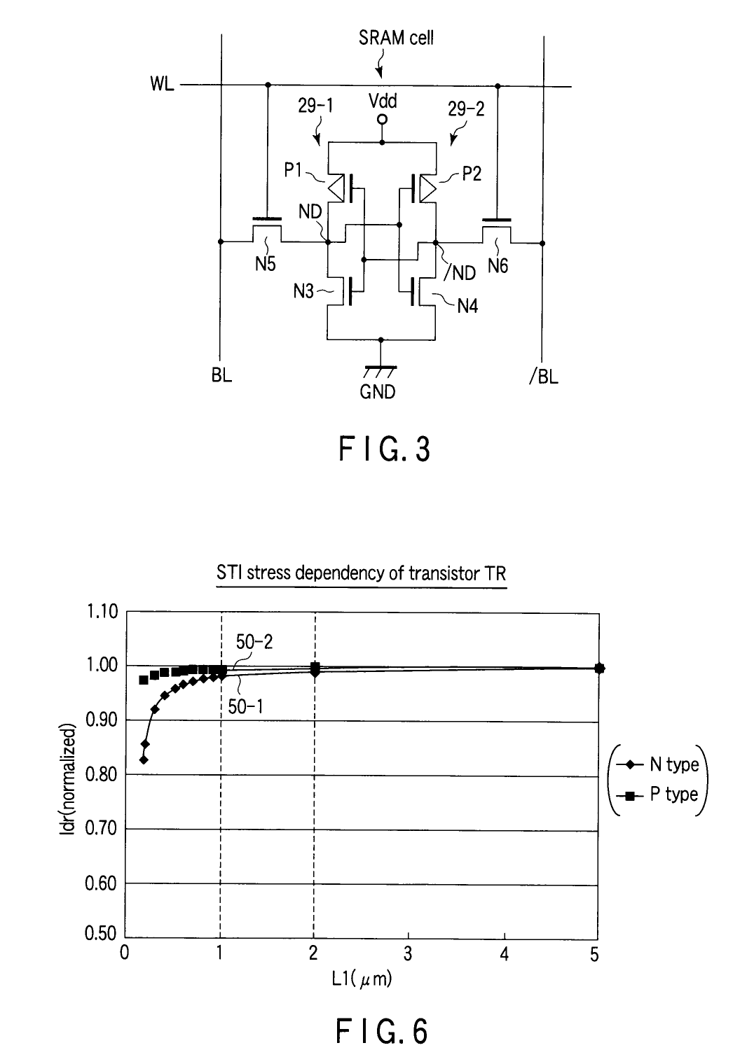

Next, a structure example of the SRAM cell according to the present embodiment is described with reference to FIG. 3.

As shown in FIG. 3, the SRAM cell according to the present embodiment is composed of transfer transistors (Transfer Tr) N5 and N6, and inverter circuits 29-1 and 29-2 which are connected in a flip-flop fashion so as to execute data storage.

One end of the current path of the transfer transistor N5 is connected to a bit line BL, the other end of current path of the transfer transistor N5 is connected to a node ND of the inverter circuit 29-1, and the gate of the transfer transistor N5 is connected to a word line WL. One end of the current path of the transfer transistor N6 is connected to a bit line /BL, the other end of current path of the transfer transistor N6 is connected to a node /ND of the inverter circuit 29-2, and the gate of the transfer transistor N6 is connected to the word line WL.

The inverter circuit 29-1 includes a load transistor (Load Tr or pull-up Tr) P1, and a driver transistor (Driver Tr or pull-down Tr) N3. One end of the current path of the driver transistor N3 is connected to a ground power supply GND, the other end of the current path of the driving transistor N3 is connected to one end of the current path of the load transistor P1 at the node ND, and the gate of the driving transistor N3 is connected to the gate of the load transistor P1 and to the node /ND of the inverter circuit 29-2. The other end of the current path of the load transistor P1 is connected to an internal power supply Vdd.

The inverter circuit 29-2 includes a load transistor P2 and a driving transistor N4. One end of the current path of the driving transistor N4 is connected to the ground power supply GND, the other end of the current path of the driving transistor N4 is connected to one end of the current path of the load transistor P2 at the node /ND, and the gate of the driving transistor N4 is connected to the gate of the load transistor P2 and to the node ND of the inverter circuit 29-1. The other end of the current path of the load transistor P2 is connected to the internal power supply Vdd.

### 3. Example of Plan-view Layout of Word Line Driver

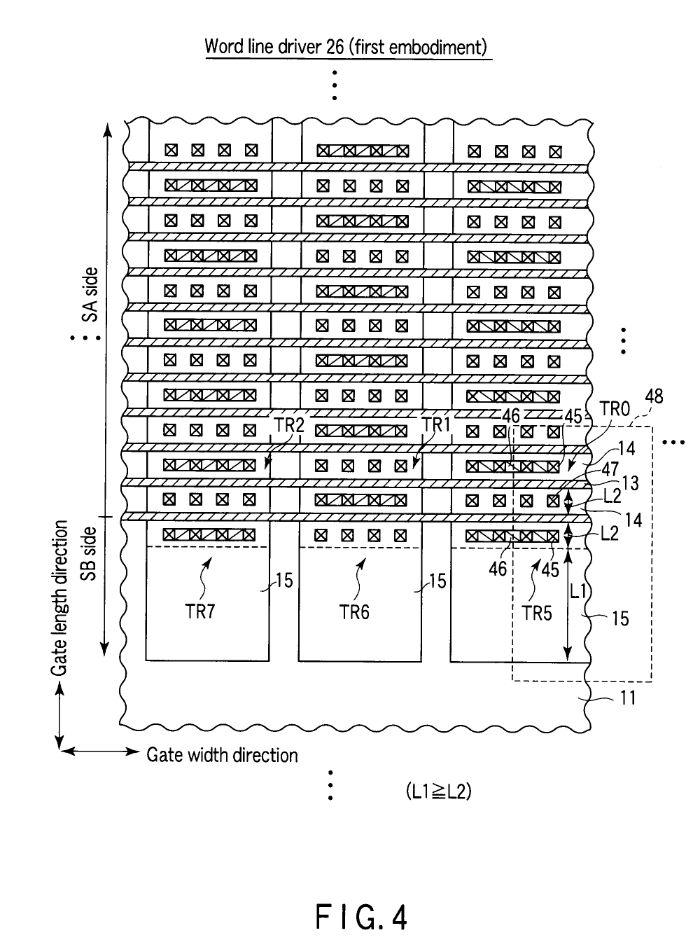

Next, an example of the plan-view layout of the word line driver is described with reference to FIG. 4. The word line driver 26 is composed of a plurality of transfer transistors which are disposed in a matrix on the semiconductor substrate. In this example, transfer transistors TR0 to TR7 are shown. One end of a current path, which is a source/drain of each of the transfer transistors TR0 to TR7, is connected to an associated one of the word lines.

It is necessary to dispose the word line driver 26 within the row pitch of the memory cell array. Thus, the transfer transistors, which are disposed along the gate width direction, share their gate electrodes. For example, the transfer transistors TR5, TR6 and TR7, which are disposed along the gate width direction, share a gate electrode 13. In addition, the transfer transistors, which neighbor in the gate length direction, share one of the impurity diffusion layers which are the source and drain. For example, the transfer transistors TR0 and TR5, which neighbor in the gate length direction, share one of the impurity diffusion layers 14 which are the source and drain.

Each of the transfer transistors includes contact wirings 45 and 47 which are provided on the surfaces of the impurity diffusion layers 14 which are the source and drain. Wirings 46 are disposed on the contact wirings 45 in a staggered fashion.

A transfer transistor (e.g. transfer transistor TR0, TR1, or TR2) on the central part (SA side) of the word line driver 26 is disposed with a sufficient distance between the STI 11 and the impurity diffusion layer 14. Thus, the transfer transistor on the central part (SA side) is little affected by the STI stress, and the driving current thereof is not decreased.

On the other hand, a transfer transistor (e.g. transfer transistor TR5, TR6, or TR7) at a terminal end (SB side) of the word line driver 26 neighboring the STI is disposed in such a layout that there is no transfer transistor which shares the impurity diffusion layer. Thus, the transfer transistor at the terminal end (SB side) of the word line driver 26 has, formally, a minimum distance from the STI 11, which is determined by design rules. Hence, this transfer transistor has a least distance from the STI.

In the present example, however, the transfer transistor (e.g. transfer transistor TR5, TR6, or TR7), which is positioned at the terminal end (SB side) of the word line driver 26, includes the redundant impurity diffusion layer 15. Thus, such a layout can be realized that the impurity diffusion layer 14, which functions as the source, is extended to such a distance as to be free from the influence of the STI stress. Therefore, a decrease in driving current of the transfer transistor (e.g. TR5, TR6 or TR7) can advantageously be prevented.

### 4. Structure Example of Transfer Transistor at Terminal End Portion of Word Line Driver

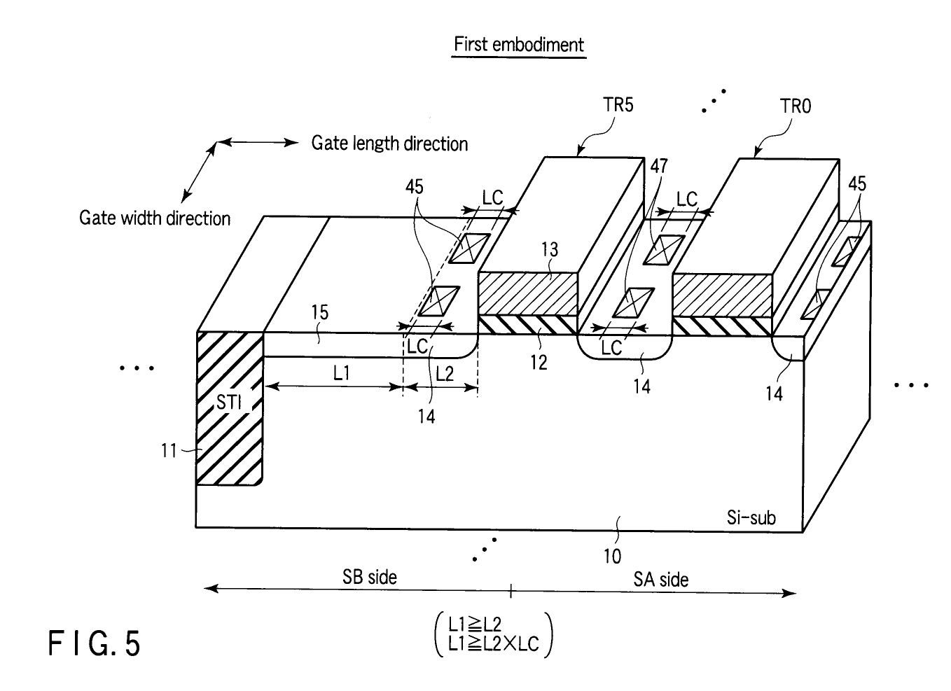

FIG. 5 is a perspective view showing a structure indicated by a broken-line box 48 in FIG. 4. As shown in FIG. 5, this structure comprises a device isolation insulating film (STI) 11 which is provided in a semiconductor substrate 10, and a transfer transistor TR5 which is disposed adjacent to the device isolation insulating film 11 in a gate length direction. The transfer transistor TR5 includes a gate insulation film 12 which is provided on the semiconductor substrate; a gate electrode 13 which is provided on the gate insulation film; a pair of impurity diffusion layers 14 which are provided spaced apart in the semiconductor substrate in a manner to sandwich the gate electrode; and a redundant impurity diffusion layer 15 which is provided between the device isolation insulating film and one of the pair of impurity diffusion layers.

The impurity diffusion layer 14 is a diffusion layer which functions as a current path of the transistor TR and on a surface of which a contact wiring 45, 47 is provided. The redundant impurity diffusion layer 15 is a diffusion layer, on a surface of which the contact wiring 45, 47 is not provided, and which has a length L1 in the gate length direction that is about double or more the length LC of the contact wiring 45, 47 in the gate length direction (L1≧2×LC).

Preferably, the length L1 in the gate length direction of the redundant impurity diffusion layer 15 should be the length L2 or more in the gate length direction of the impurity diffusion layer 14 (L1≧L2). In the present example, the length L1 in the gate length direction of the redundant impurity diffusion layer 15 should preferably be, e.g. about 1 μm or more. More preferably, the length L1 in the gate length direction of the redundant impurity diffusion layer 15 should be, e.g. about 2/μm or more.

In this example, the device isolation insulating film 11 is formed of a silicon oxide (SiO₂) film which is buried in the semiconductor substrate 10. However, the device isolation insulating film 11 is not limited to this example.

### 5. Advantageous Effects of the Present Embodiment

At least the following advantageous effects (1) to (3) can be obtained by the semiconductor device and the manufacturing method thereof according to the present embodiment.

(1) The stress due to the device isolation insulating film can be relaxed, and a decrease in driving current can be prevented.

As described above, the structure according to the present embodiment comprises a device isolation insulating film (STI) 11 which is provided in a semiconductor substrate 10, and a transfer transistor TR5 which is disposed adjacent to the device isolation insulating film 11 in a gate length direction. The transfer transistor TR5 includes a gate insulation film 12 which is provided on the semiconductor substrate; a gate electrode 13 which is provided on the gate insulation film; a pair of impurity diffusion layers 14 which are provided spaced apart in the semiconductor substrate in a manner to sandwich the gate electrode; and a redundant impurity diffusion layer 15 which is provided between the device isolation insulating film and one of the pair of impurity diffusion layers.

The above-described structure includes the redundant impurity diffusion layer 15 which is provided between the device isolation insulating film 11 and one of the pair of impurity diffusion layers 14. Thus, such a layout structure can be realized that one of the impurity diffusion layers 14 is extended to such a distance as to be free from the influence of the stress due to the device isolation insulating film 11, and the stress (STI stress) due to the device isolation insulating film 11 can be relaxed. Therefore, a decrease in driving current of the transistor TR5 can be prevented.

In this example, as shown in FIG. 6, a decrease in driving current of the transfer transistor can be prevented. FIG. 6 is a graph showing the STI stress dependency (Idr-W1) of the transfer transistor. In FIG. 6, a solid line 50-1 is a characteristic line in the case where the transfer transistor is constructed as a P-type MOS transistor. In FIG. 6, a solid line 50-2 is a characteristic line in the case where the transfer transistor is constructed as an N-type MOS transistor.

As shown in FIG. 6, in each case of the characteristic lines 50-1 and 50-2, L1 is about 1 μm or more. Thus, the value (normalized) of the current driving current Idr is in the neighborhood of 1.0, and it is clear that a decrease in driving current can be prevented. Further, in the case where L1 is about 2 μm or more, in each of the characteristic lines 50-1 and 50-2, the value (normalized) of the current driving current Idr is about 1.0, and it is clear that there is substantially no decrease in driving current.

As described above, the structure of this embodiment is advantageous in that the stress due to the device isolation insulating film can be relaxed, and a decrease in driving current can be prevented.

(2) The manufacturing cost can advantageously be reduced.

The redundant impurity diffusion layer 15 according to this example is provided between the device isolation insulating film (STI) 11 and one of the pair of impurity diffusion layers 14.

In other words, in this layout, the source, which is the impurity diffusion layer 14, is extended.

Thus, neither an additional fabrication step nor an additional mask is needed in order to form the redundant impurity diffusion layer 15, and the redundant impurity diffusion layer 15 can be formed at the same time as the impurity diffusion layer 14.

### <Manufacturing Method>

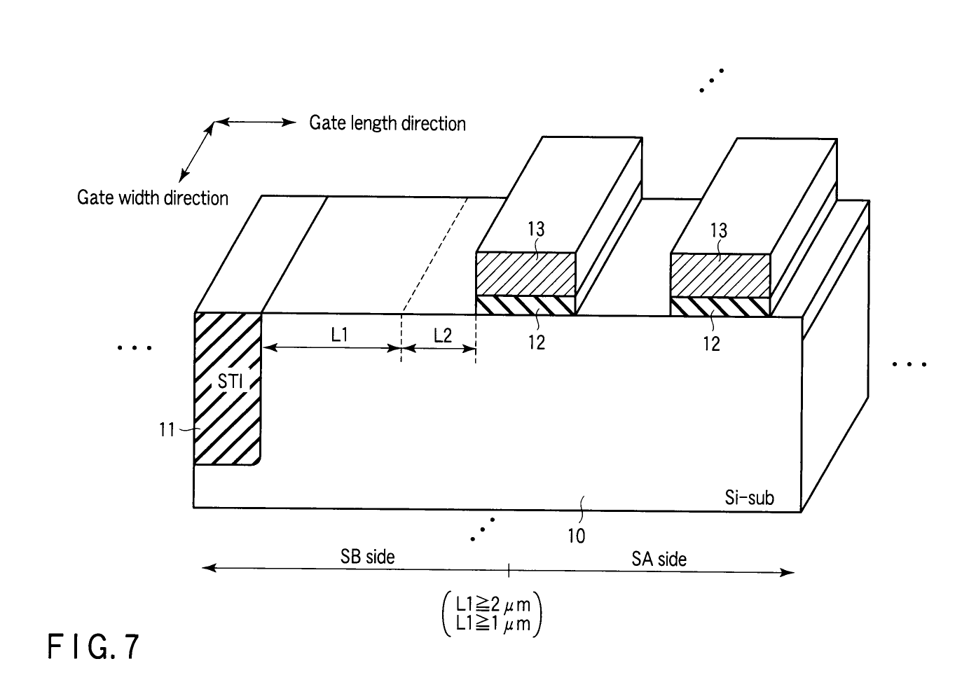

An example of the manufacturing method of the word line control circuit 26 according to this embodiment is as illustrated in FIG. 7 to FIG. 9.

To start with, as shown in FIG. 7, a trench is formed in the semiconductor substrate 10 in the device isolation region. A silicon oxide film, for instance, is buried in the trench. Thereby, the device isolation insulating film (STI) 11 is formed.

Then, a line & space pattern of a multi-layer, which comprises the gate insulation film 12 and gate electrode 13, is formed on the semiconductor substrate 10 in the device region in the gate width direction by, e.g. photolithography. At this time, preferably, the patterning should be performed such that the length L1 in the gate length direction of the redundant impurity diffusion layer 15, which is formed in a subsequent step, may become, e.g. about 2 μm or more. More preferably, the patterning should be performed such that the length L1 in the gate length direction of the redundant impurity diffusion layer 15 may become, e.g. about 1 μm or more.

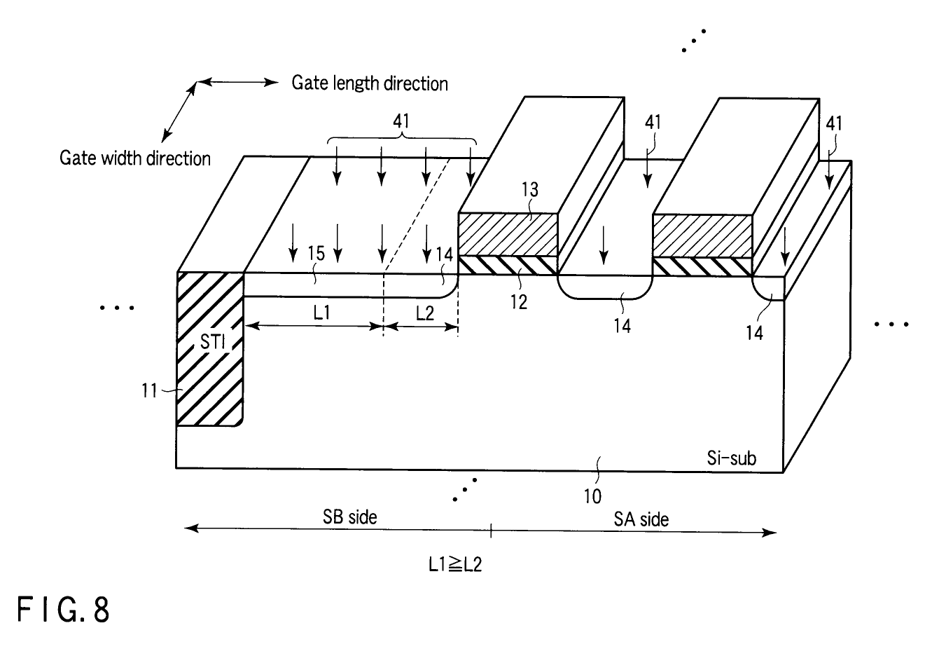

Then, as shown in FIG. 8, using the above-described pattern as a mask, N-type impurities 41, such as phosphorus (P) or arsenic (As), are doped in the semiconductor substrate 10 by, e.g. ion implantation. Thereby, the impurity diffusion layers 14 and redundant impurity diffusion layer 15, which function as the source/drain, are formed at the same time.

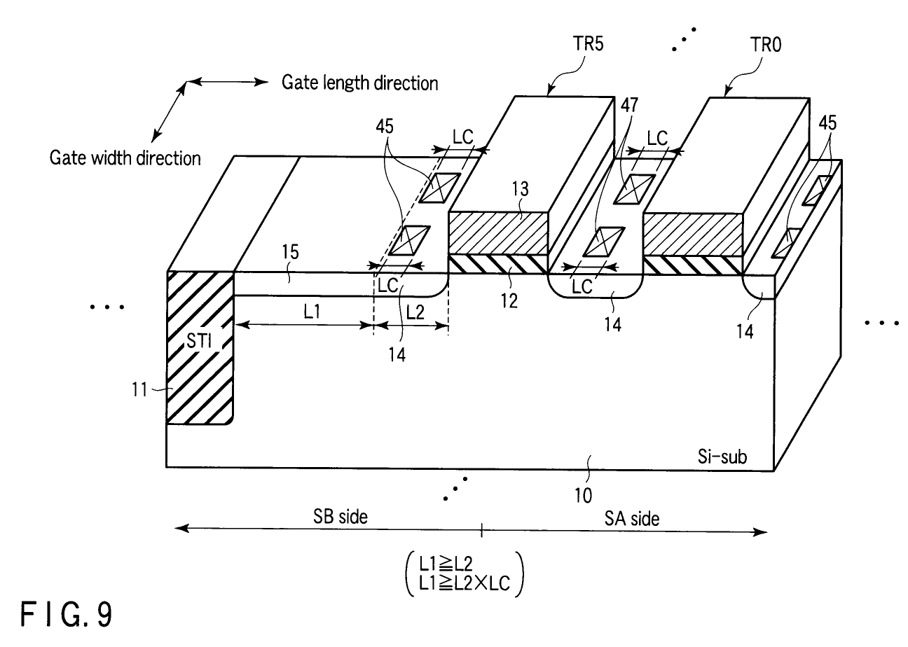

Subsequently, as shown in FIG. 9, contact wirings 45 and 47 are formed on the impurity diffusion layers 14, and transistors RT0 and TR5 are formed. At this time, preferably, the length L1 in the gate length direction of the redundant impurity diffusion layer 15 should be set at about double or more the length LC of the contact wiring 45, 47 in the gate length direction (L1≧2×LC).

As has been described above, the manufacturing cost can advantageously be reduced in that the redundant impurity diffusion layer 15 can be formed at the same time as the impurity diffusion layers 14, and the number of fabrication steps or masks does not increase.

(3) The controllability of the word line driver 26 can advantageously be improved.

As described above, the semiconductor device according to the present embodiment is applied to the transfer transistors (TR5, TR6, TR7, etc.) of the word line control circuit 26.

Thus, in these transfer transistors (TR5, TR6, TR7, etc.), the stress due to the device isolation insulating film can be relaxed, and a decrease in driving current can be prevented.

As a result, it is possible to prevent the driving current of the transfer transistors (TR5, TR6, TR7, etc.) from varying due to the STI stress, and there occurs no difference in driving current between these transfer transistors and other transfer transistors (TR0, TR1, TR2, etc.). Therefore, since it is possible to prevent a difference from occurring in the timing of activating/de-activating the word lines, the controllability of the word line driver 26 can advantageously be improved.

[Modification (An Example in which Only an NMOS Transistor has a Redundant Impurity Diffusion Layer)]

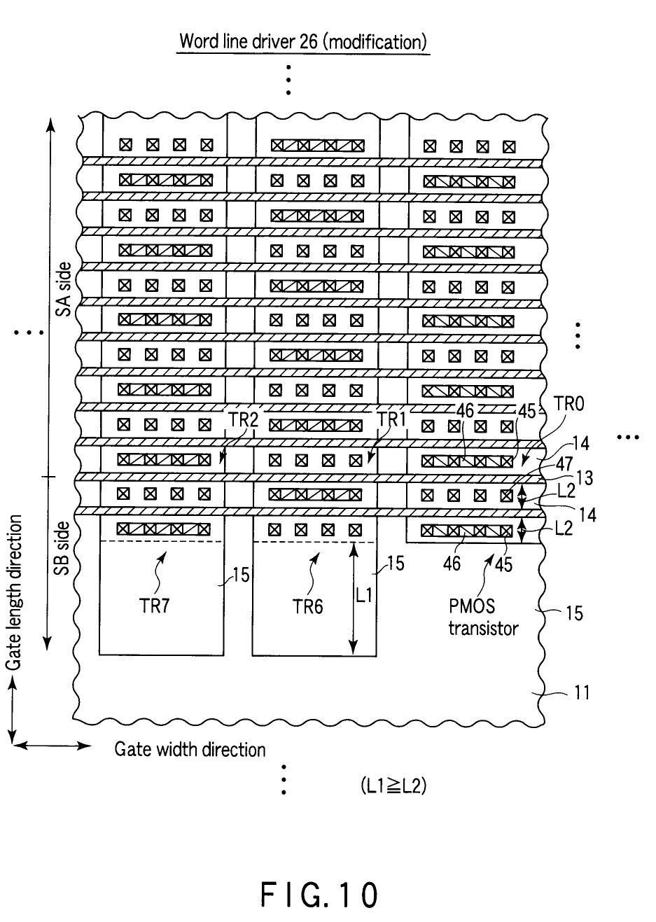

Next, a semiconductor memory device according to a modification is described with reference to FIG. 10. This modification relates to an example in which only an NMOS transistor has a redundant impurity diffusion layer. In the description below, a detailed description of the parts common to those in the first embodiment is omitted.

In the first embodiment, a description has been given of the layout structure in which the PMOS/NMOS transistors that constitute the word line driver 26 have the redundant impurity diffusion layers 15 and the source-side regions are extended.

However, in a case where the influence of the STI stress is large with respect to only one of a PMOS transistor and an NMOS transistor, the layout may be modified, for example, as shown in FIG. 10. In the example shown in FIG. 10, the redundant impurity diffusion layer 15 is provided only on the NMOS side, and the source-side impurity diffusion region is extended, whereas the PMOS transistor does not have the redundant impurity diffusion layer 15. In this respect, the example of FIG. 10 differs from the above-described first embodiment.

According to this modification, at least the same advantageous effects (1) to (3) as described above can be obtained. Further, this modification is effective in the case where the influence of the STI stress is large with respect to only one of a PMOS transistor and an NMOS transistor.

### SECOND EMBODIMENT

### An Example in which a Redundant Impurity Diffusion Layer is Shared

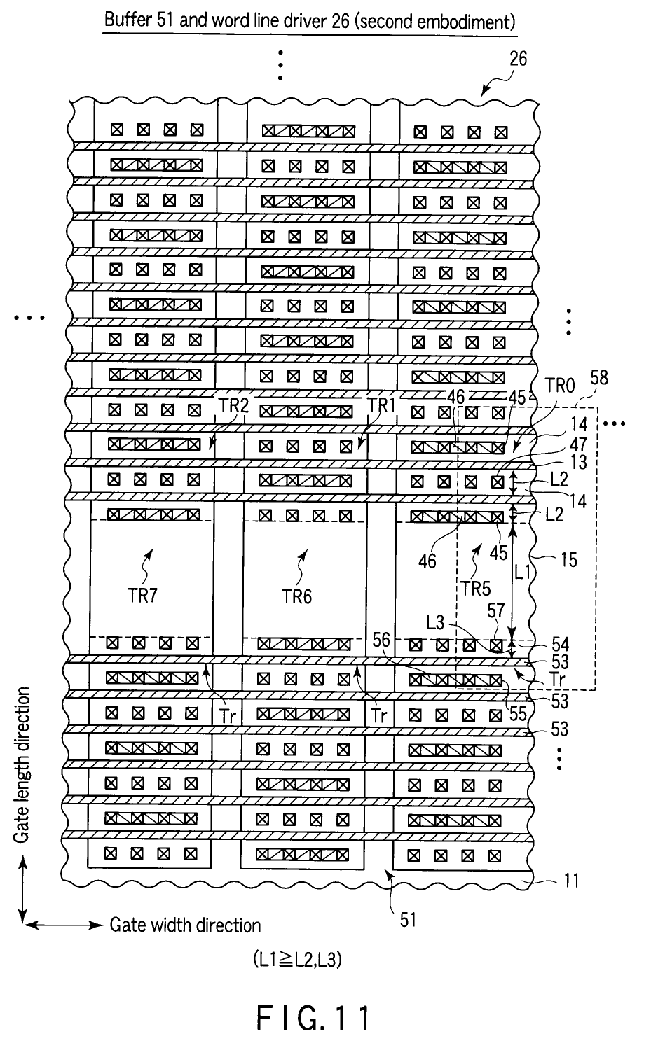

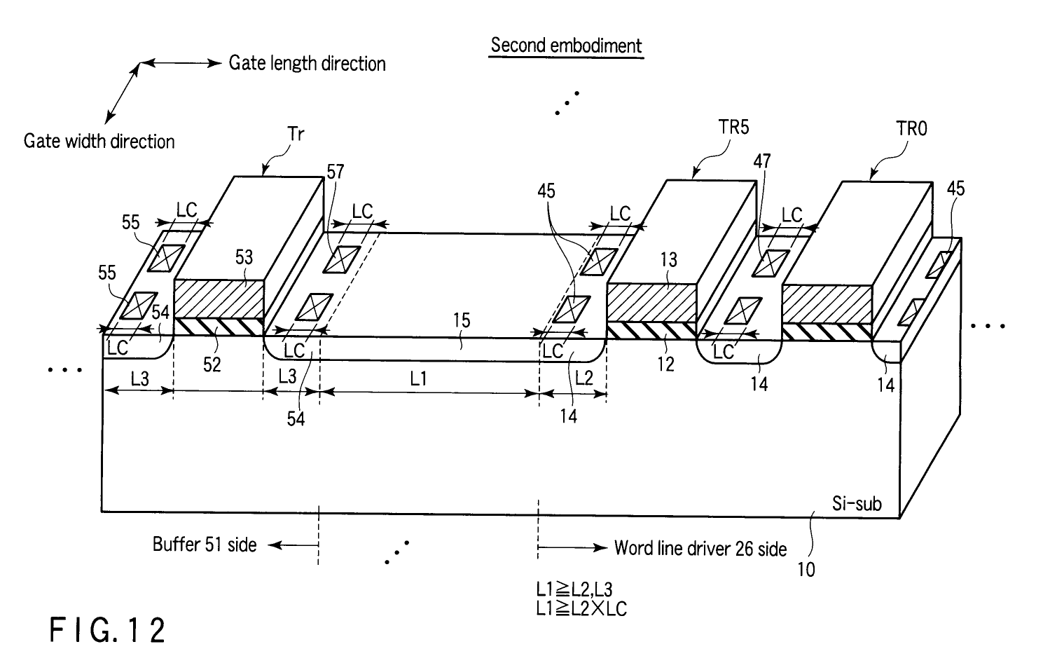

Next, a semiconductor memory device according to a second embodiment of the invention is described with reference to FIG. 11 and FIG. 12. This embodiment relates to an example in which a redundant impurity diffusion layer is shared. In the description below, a detailed description of the parts common to those in the first embodiment is omitted.

As shown in FIG. 11 and FIG. 12, the second embodiment differs from the first embodiment with respect to the structure in which the redundant impurity diffusion layer 15 is shared between first and second transistors TR and Tr, which are located at the terminal ends of the word line driver 26 and buffer 51.

The buffer 51 is disposed in order to drive a local sense amplifier (not shown) in the word line driver 26. For example, this structure is applied to the case in which bit lines are formed in a multi-layer structure and memory cell arrays (not shown), which are disposed over and under the word line driver 26, share the local sense amplifier.

The buffer 51 includes a plurality of transistors Tr which are arranged in a matrix. FIG. 12 is a perspective view of a structure indicated by a broken-line box in FIG. 11.

As shown in FIG. 12, the first and second transistors TR5 and Tr, which share the redundant impurity diffusion layer 15, are disposed adjacent to each other in the gate length direction. The second transistor Tr, which neighbors the first transistor TR5 in the gate length direction, is disposed on the semiconductor substrate 10. The second transistor Tr comprises a gate insulation film 52 which is provided on the semiconductor substrate 10; a gate electrode 53 provided on the gate insulation film; and a pair of impurity diffusion layers 54 which are provided spaced apart in the semiconductor substrate in a manner to sandwich the gate electrode. The redundant impurity diffusion layer 15, which is in contact with one of the paired impurity diffusion layers 54, is shared with the first transistor TR5. In other words, the redundant impurity diffusion layer 15 in this embodiment is provided in the semiconductor substrate 10 in such a manner that the redundant impurity diffusion layer 15 is interposed between the impurity diffusion layers 14 and 54 of the first and second transistors TR5 and Tr.

The impurity diffusion layer 54 is a diffusion layer which functions as a current path of the transistor Tr, and on a surface of which a contact wiring 55, 57 is provided. The redundant impurity diffusion layer 15 is a diffusion layer, on a surface of which the contact wiring 45, 47, 55, 57 is not provided, and which has a length L1 in the gate length direction that is about double or more the length LC of the contact wiring 45, 47, 55, 57 in the gate length direction (L1≧2×LC).

Preferably, the length L1 in the gate length direction of the redundant impurity diffusion layer 15 should be the length L2 or more in the gate length direction of the impurity diffusion layer 14 and should be the length L3 or more in the gate length direction of the impurity diffusion layer 54 (L≧L2, L3). In this embodiment, like the preceding embodiment, the length L1 in the gate length direction of the redundant impurity diffusion layer 15 should preferably be, e.g. about 1 μm or more. More preferably, the length L1 in the gate length direction of the redundant impurity diffusion layer 15 should be, e.g. about 2 μm or more.

As has been described above, according to the semiconductor device of this embodiment, at least the same advantageous effects (1) to (3) as described above can be obtained.

In addition, according to the structure of this embodiment, the redundant impurity diffusion layer 15 is shared between the first and second transistors TR and Tr at the terminal ends of the word line driver 26 and buffer 51. Thus, in this layout, the transistors TR and Tr at the terminal ends of the word line driver 26 and buffer 51 do not neighbor the device isolation insulating film (STI) 11.

Therefore, this embodiment is more advantageous in that the occurrence of the STI stress is suppressed and there is no degradation in driving current of the first and second transistors TR and Tr.

### THIRD EMBODIMENT

### An Example in which the Invention is Applied to a Bit Line Load

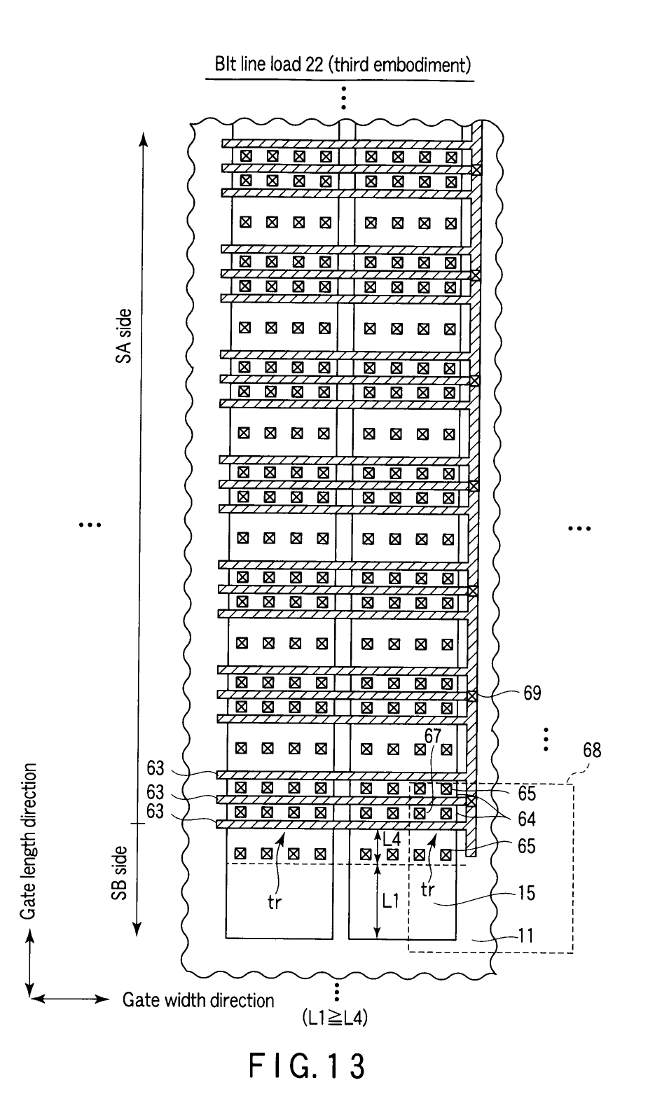

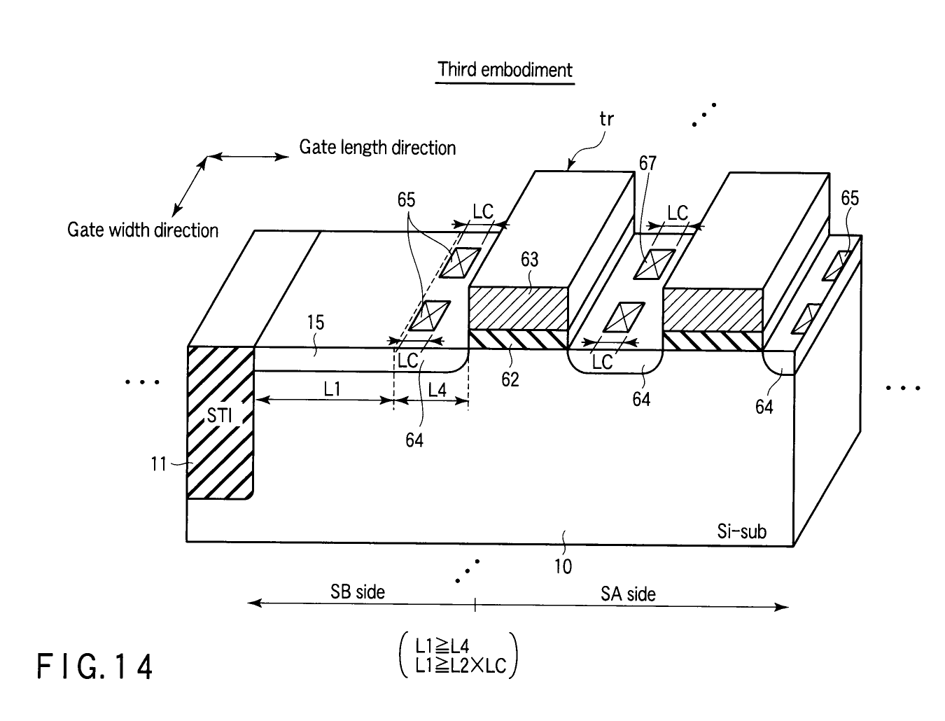

Next, a semiconductor memory device according to a third embodiment of the invention is described with reference to FIG. 13 and FIG. 14. This embodiment relates to an example in which the invention is applied to a bit line load 22. In the description below, a detailed description of the parts common to those in the first embodiment is omitted.

As shown in FIG. 13 and FIG. 14, the bit line load 22 includes a plurality of transistors tr (bit line load PMOS) which are arranged in a matrix. In the bit line load 22, transistors tr (bit line load PMOS) are disposed on each bit line and are connected so as to charge or equalize the bit line.

An impurity diffusion layer 64, which is the source of the transistor tr (bit line load PMOS), is connected to a power supply via a contact wiring 65, and is shared with a neighboring transistor tr.

The transistor tr, which is disposed at a terminal end of the bit line load 22, includes a redundant impurity diffusion layer 15. Thus, the impurity diffusion layer 64, which functions as the source, can be extended to such a distance as to be free from the influence of STI stress. In the structure of the third embodiment, like the first embodiment, the distance from the STI 11 is secured so that the impurity diffusion layer 64 is free from the STI stress. Thereby, it is possible to prevent a difference from occurring in driving current between transistors tr disposed on the array central part side (SA side) and transistors tr disposed on the array terminal end side (SB side).

FIG. 14 is a perspective view showing a structure indicated by a broken-line box 68 in FIG. 13.

As shown in FIG. 14, the transistor tr is disposed adjacent to the device isolation insulating film (STI) 11 in the gate length direction. The transistor tr comprises a gate insulation film 62 which is provided on the semiconductor substrate 10; a gate electrode 63 provided on the gate insulation film; a pair of impurity diffusion layers 64 which are provided spaced apart in the semiconductor substrate in a manner to sandwich the gate electrode; and a redundant impurity diffusion layer 15 which is provided between one of the paired impurity diffusion layers 64 and the device isolation insulating film 11.

Preferably, the length L1 in the gate length direction of the redundant impurity diffusion layer 15 should be the length L4 or more in the gate length direction of the impurity diffusion layer 54 (L1≧L4). In this embodiment, like the preceding embodiments, the length L1 in the gate length direction of the redundant impurity diffusion layer 15 should preferably be, e.g. about 1 μm or more. More preferably, the length L1 in the gate length direction of the redundant impurity diffusion layer 15 should be, e.g. about 2 μm or more.

As has been described above, according to the semiconductor device of this embodiment, at least the same advantageous effects (1) to (3) as described above can be obtained.

In addition, as in the present embodiment, the invention may be applied, where necessary, to the bit line load 22 of the SRAM.

### FOURTH EMBODIMENT

### An Example in which the Invention is Applied to a NAND Flash Memory

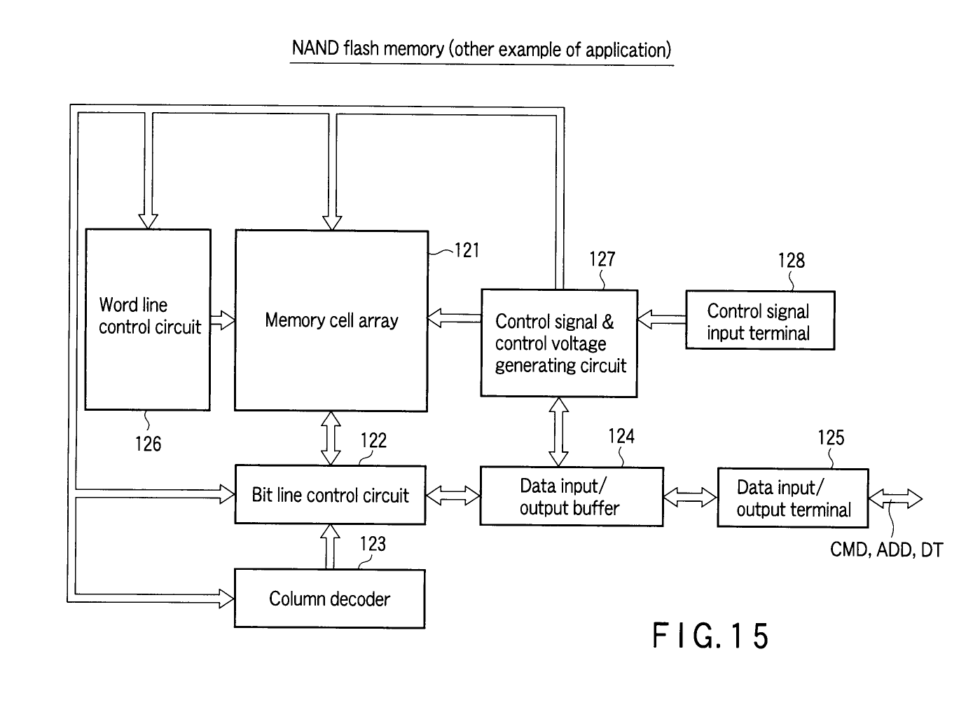

Next, referring to FIG. 15 to FIG. 18, a semiconductor device according to a fourth embodiment of the invention is described. In this embodiment, the case in which the invention is applied to a word line control circuit of a NAND flash memory is described by way of example.

### <Example of Entire Structure>

To begin with, referring to FIG. 15, a description is given of an example of the entire structure of the NAND flash memory. FIG. 15 is a block diagram showing the NAND flash memory according to this embodiment.

As shown in FIG. 15, the NAND flash memory comprises a memory cell array 121, a bit line control circuit 122, a column decoder 123, a data input/output buffer 124, a data input/output terminal 125, a word line control circuit 126, a control signal & control voltage generating circuit 127, and a control signal input terminal 128.

The memory cell array 121 is composed of a plurality of blocks. The word line control circuit 126 for controlling word lines, the bit line control circuit 122 for controlling bit lines and the control signal & control voltage generating circuit 127 are connected to the memory cell array 121.

The bit line control circuit 122 reads data of memory cells in the memory cell array 121 via the bit lines, and detects the states of the memory cells in the memory cell array 121 via the bit lines. In addition, the bit line control circuit 122 executes data write in the memory cells by applying write control voltages to the memory cells in the memory cell array 121 via the bit lines. The column decoder 123, the data input/output buffer 124 and the control signal & control voltage generating circuit 127 are connected to the bit line control circuit 122.

Data memory circuits (not shown) are provided in the bit line control circuit 122, and the data memory circuits are selected by the column decoder 123. The data of the memory cells, which are read into the data memory circuits, are output to the outside from the data input/output terminal 125 via the data input/output buffer 124. The data input/output terminal 125 is connected to, for example, a host device which is disposed outside the NAND flash memory.

The host device is, for instance, a microcomputer, which receives data that is output from the data input/output terminal 125. Further, the host device outputs various commands CMD which control the operation of the NAND flash memory, addresses ADD and data DT. Write data, which is input to the data input/output terminal 125 from the host device, is delivered via the data input/output buffer 124 to the data memory circuits (not shown) which are selected by the column decoder 123. On the other hand, the commands and addresses are delivered to the control signal & control voltage generating circuit 127.

The word line control circuit 126 selects the word lines in the memory cell array 121, and applies voltages necessary for data read, write or erase to the selected word lines.

The control signal & control voltage generating circuit 127 is connected to the memory cell array 121, bit line control circuit 122, column decoder 123, data input/output buffer 124 and word line control circuit 126. These connected structural circuits are controlled by the control signal & control voltage generating circuit 127. The control signal & control voltage generating circuit 127 is connected to the control signal input terminal 128, and is controlled by control signals, such as an ALE (address latch enable) signal, which are input from the host device via the control signal input terminal 128.

The word line control circuit 126, bit line control circuit 122, column decoder 123 and control signal & control voltage generating circuit 127 constitute a write circuit and a read circuit.

### <Structure Example of the Block>

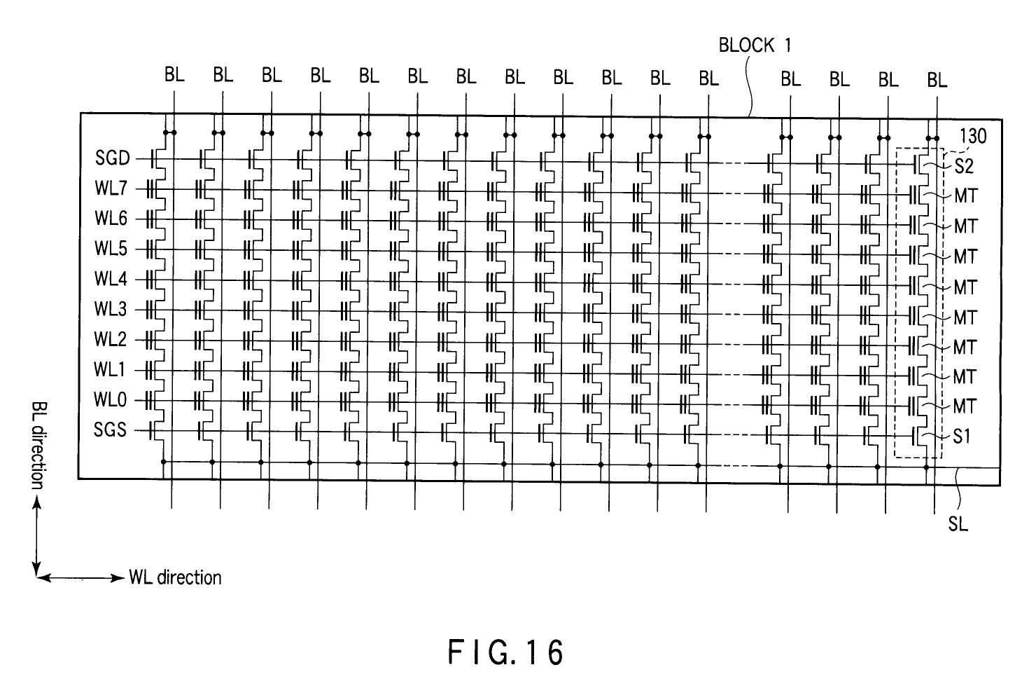

Next, a structure example of the blocks, which constitute the memory cell array 121, is described with reference to FIG. 16. In this description, one block BLOCK1 is exemplified. In the case of this example, the memory cells in the block BLOCK1 are erased batchwise. In other words, the block is an erase unit.

The block BLOCK1 is composed of a plurality of memory cell strings 130 which are arranged in the word line direction (WL direction). The memory cell string 130 comprises a NAND string which is composed of eight memory cells MT having series-connected current paths, a select transistor S1 which is connected to one end of the NAND string, and a select transistor S2 which is connected to the other end of the NAND string.

In the present example, the NAND string is composed of eight memory cells MT. However, it should suffice if the NAND string is composed of two or more memory cells, and the number of memory cells is not limited to eight. The select transistor S1 is connected to a source line SL, and the select transistor S2 is connected to the bit line BL.

Word lines WL extend in the WL direction and are commonly connected to a plurality of memory cells MT which are arranged in the WL direction. A select gate line SGS extends in the WL direction and is commonly connected to a plurality of select transistors S1 which are arranged in the WL direction. A select gate line SGD also extends in the WL direction and is commonly connected to a plurality of select transistors S2 which are arranged in the WL direction.

### <Example of Cross-Sectional Structure of Memory Cell String>

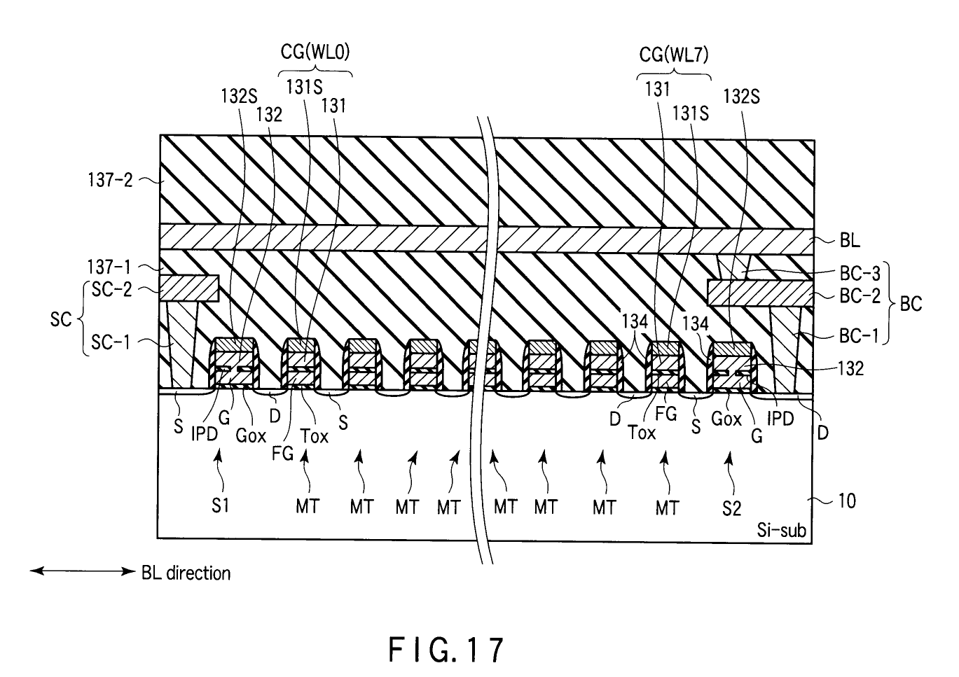

Next, an example of the cross-sectional structure of the memory string is described with reference to FIG. 17. FIG. 17 shows the cross-sectional structure of the memory cell string in the bit line direction.

As shown in FIG. 17, the memory cell string is composed of the select transistors S1 and S2 and the memory cells MT.

Each memory cell MT has a MISFET structure which is provided at an intersection between the bit line BL and word line WL. The source S/drain D, which is the current path of the memory cell MT, is connected in series to the neighboring memory cell MT. One end of the current path is connected to the bit line BL via the select transistor S2 that is composed of a MISFET, and the other end of the current path is connected to the source line SL via the select transistor S1 that is composed of a MISFET.

Each of the memory cells MT has a multi-layer structure comprising a tunnel insulation film Gox which is provided on a P-well (not shown) that is formed in the semiconductor substrate 10; a floating electrode FG which is provided on the tunnel insulation film Gox; an inter-gate insulation film Tox which is provided on the floating electrode FG; and a control electrode CG (word line WL) which is provided on the inter-gate insulation film Tox. The control electrode CG is formed of a polysilicon layer 131 and a silicide layer 131S which is provided on the polysilicon layer 131. The floating electrode FG is electrically isolated in each memory cell MT. In the memory cells MT disposed in the WL direction, the control electrodes CG are electrically commonly connected.

Each of the memory cells MT has spacers 134 which are provided along side walls of the multi-layer structure, and a source S and a drain D which are provided in the semiconductor substrate (P-well) 10 so as to sandwich the multi-layer structure.

The select transistor S1, S2 includes a gate insulation film Gox, an inter-gate insulation film IPD, and a gate electrode G. The inter-gate insulation film IPD is split at its central part, and the upper and lower layers of the inter-gate insulation film IPD are configured to be electrically connected. The gate electrode G is formed of, for instance, a polysilicon layer 132 and a silicide layer 132S which is provided on the polysilicon layer 132.

The select transistor S1, S2 includes spacers 134 which are provided along side walls of the gate electrode G, and a source S and a drain D which are provided in the semiconductor substrate (P-well) 10 so as to sandwich the gate electrode G.

The bit line BLm is electrically connected to the drain D of the select transistor S2 via bit line contacts BC-1 to BC-3 in an interlayer insulation film 137-1.

The source line SL is electrically connected to the source S of the select transistor S1 via source line contacts SC-1 and SC-2 in the interlayer insulation film 137-1.

### <Structure Example of Word Line Control Circuit>

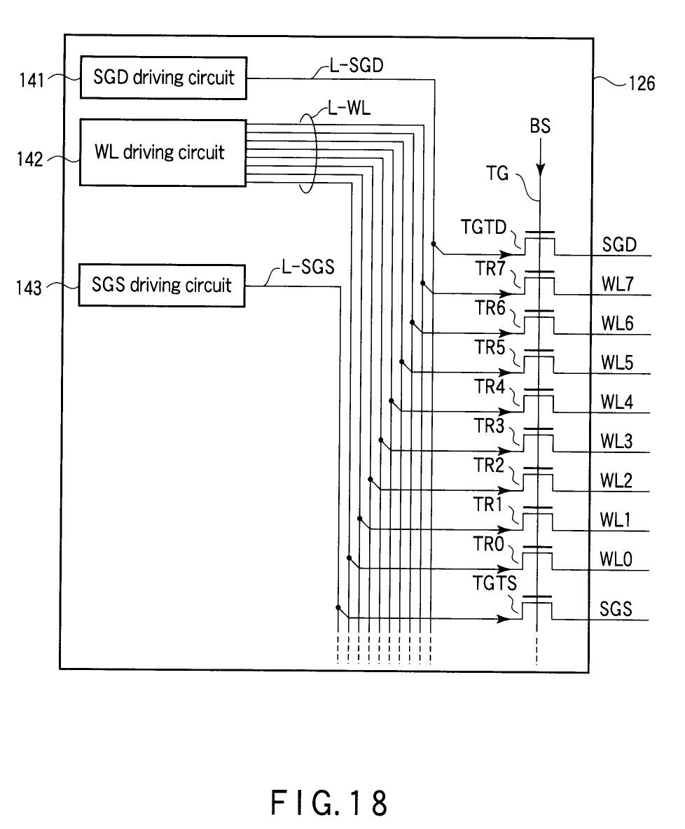

Next, a structure example of the word line control circuit is described with reference to FIG. 18. FIG. 18 shows a structure example of the word line control circuit 126 according to this embodiment.

As shown in FIG. 18, the word line control circuit 126 according to this embodiment includes transfer transistors TGTD, TGTS and TR0 to TR7, an SGD driving circuit 141, a WL driving circuit 142 and an SGS driving circuit 143.

The transfer transistors TGTD, TGTS and TR0 to TR7 are high-breakdown-voltage transistors having gates commonly connected to a transfer gate line TG. A block select signal BS, which selects one of the blocks, is input to the transfer gate line TG.

One end of the current path of the transfer transistor TGTD is connected to the select gate SGD, and the other end of the current path thereof is connected to the SGD driving circuit 141 via a wiring line L-SGD. The transfer transistor TGTD, the wiring line L-SGD and the SGD driving circuit 141 constitute a select gate voltage generating circuit.

One end of the current path of the transfer transistor, TR0 to TR7, is connected to the word line, WL0 to WL7, and the other end of the current path thereof is connected to the WL driving circuit 142 via a wiring line L-WL. The transfer transistors TR0 to TR7, the wiring line L-WL and the WL driving circuit 142 constitute a word line voltage generating circuit.

One end of the current path of the transfer transistor TGTS is connected to the select gate SGS, and the other end of the current path thereof is connected to the SGS driving circuit 143 via a wiring line L-SGS. The transfer transistor TGTS, the wiring line L-SGS and the SGS driving circuit 143 constitute a select gate voltage generating circuit.

As has been described above, also in the case in which the invention is applied to the word line driving circuit 126 or bit line driving circuit 122 of the NAND flash memory, as well as to the SRAM, at least the same advantageous effects (1) to (3) as described above can be obtained. The invention is applicable, where necessary, to the NAND flash memory. The NAND flash memory is one of storage devices, whose scaling has been most developed in recent years. Thus, it is a great merit to prevent a decrease in driving current of the transistor due to the STI stress.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a device isolation insulating film which is provided in a semiconductor substrate; and
an insulated-gate field-effect transistor which is disposed adjacent to the device isolation insulating film in a gate length direction, the insulated-gate field-effect transistor including a gate insulation film which is provided on the semiconductor substrate, a gate electrode which is provided on the gate insulation film, a pair of impurity diffusion layers which are provided spaced apart in the semiconductor substrate in a manner to sandwich the gate electrode, and a redundant impurity diffusion layer which is provided between the device isolation insulating film and one of the pair of impurity diffusion layers.

2. The device according to claim 1, wherein the insulated-gate field-effect transistor is an N-type MOS transistor or a P-type MOS transistor.

3. The device according to claim 1, wherein the insulated-gate field-effect transistor is disposed on a word line driver or a bit line load.

4. The device according to claim 1, wherein the insulated-gate field-effect transistor further includes a contact wiring which is provided on a surface of each of the pair of impurity diffusion layers.

5. The device according to claim 4, wherein the contact wiring is not provided on a surface of the redundant impurity diffusion layer.

6. The device according to claim 4, wherein a length in the gate length direction of the redundant impurity diffusion layer is double or more a length in the gate length direction of the contact wiring.

7. The device according to claim 1, wherein a length in the gate length direction of the redundant impurity diffusion layer is equal to or greater than a length in the gate length direction of the impurity diffusion layer.

8. A semiconductor device comprising:
a first insulated-gate field-effect transistor including a gate insulation film which is provided on a semiconductor substrate, a gate electrode which is provided on the gate insulation film, a pair of impurity diffusion layers which are provided spaced apart in the semiconductor substrate in a manner to sandwich the gate electrode, and a redundant impurity diffusion layer which is provided in contact with one of the pair of impurity diffusion layers; and
a second insulated-gate field-effect transistor which is disposed on the semiconductor substrate, adjacent to the first insulated-gate field-effect transistor in a gate length direction, the second insulated-gate field-effect transistor sharing the redundant impurity diffusion layer in contact with one of a pair of impurity diffusion layers thereof.

9. The device according to claim 8, wherein the first and second insulated-gate field-effect transistors are N-type MOS transistors or P-type MOS transistors.

10. The device according to claim 8, wherein the first and second insulated-gate field-effect transistors are disposed on a word line driver or a bit line load.

11. The device according to claim 8, wherein each of the first and second insulated-gate field-effect transistors further includes a contact wiring which is provided on a surface of each of the pair of impurity diffusion layers.

12. The device according to claim 11, wherein the contact wiring is not provided on a surface of the redundant impurity diffusion layer.

13. The device according to claim 11, wherein a length in the gate length direction of the redundant impurity diffusion layer is double or more a length in the gate length direction of the contact wiring.

14. The device according to claim 8, wherein a length in the gate length direction of the redundant impurity diffusion layer is equal to or greater than a length in the gate length direction of the impurity diffusion layer.

15. The device according to claim 8, further comprising a third insulated-gate field-effect transistor which is provided adjacent to the first insulated-gate field-effect transistor in the gate length direction, the third insulated-gate field-effect transistor including a gate insulation film which is provided on the semiconductor substrate, a gate electrode which is provided on the gate insulation film, and a pair of impurity diffusion layers which are provided spaced apart in the semiconductor substrate in a manner to sandwich the gate electrode and share one of the pair of impurity diffusion layers of the first insulated-gate field-effect transistor.

16. A method of manufacturing a semiconductor device, comprising:
forming a trench in a semiconductor substrate in a device isolation region, and burying an insulation film in the trench, thereby forming a device isolation insulating film;
forming a line & space pattern of a multi-layer, which comprises a gate insulation film and a gate electrode, in a gate width direction on the semiconductor substrate in the device isolation region;
doping impurities in the semiconductor substrate by using the pattern as a mask, and simultaneously forming an impurity diffusion layer which functions as a source/drain, and a redundant impurity diffusion layer which is interposed between the device isolation insulating film and the impurity diffusion layer in a gate length direction; and
forming a contact wiring on the impurity diffusion layer.

17. The method according to claim 16, wherein when the line & space pattern of the multi-layer, which comprises the gate insulation film and the gate electrode, is formed in the gate width direction, a distance from the device isolation insulating film is set by patterning such that a length in the gate length direction of the redundant impurity diffusion layer is greater than a length in the gate length direction of the impurity diffusion layer.

18. The method according to claim 16, wherein when the contact wiring is formed, the contact wiring is formed such that a length in the gate length direction of the redundant impurity diffusion layer is double or more a length in the gate length direction of the contact wiring.
